(19) United States
(12) Patent Application Publication
(10) Pub. No.: US 2012/0056768 A1
(43) Pub. Date: Mar. 8, 2012

(54) DIGITAL/ANALOG CONVERTER

(75) Inventor: Shigeo Imai, Yokohama-Shi (JP)

(73) Assignee: KABUSHIKI KAISHA TOSHIBA, Tokyo (JP)

(21) Appl. No.: 13/069,581

(22) Filed: Mar. 23, 2011

(30) Foreign Application Priority Data
Sep. 7, 2010 (JP) 2010-199933

(51) Int. Cl. H03M 1/66

(52) U.S. Cl. 341/144

(57) ABSTRACT

A digital/analog converter converts an input digital signal to an analog signal and outputs the analog signal. The digital/analog converter has first and second transistors that are complementarily switched by a first digital signal included in the digital signal. The digital/analog converter has a first current source having a first end connected to a first potential, and having a second end connected to a first end of the first transistor and a first end of the second transistor, to output a constant current. The digital/analog converter has a third transistor having a first end connected to a second end of the first transistor. The digital/analog converter has a fourth transistor having a first end connected to a second end of the second transistor. The digital/analog converter has a first output terminal connected to a second end of the third transistor to output a first analog signal. The digital/analog converter has a control circuit that controls gate voltages of the third transistor and the fourth transistor according to the digital signal such that the third transistor and the fourth transistor operate in a saturation region.

### CROSS-REFERENCE TO RELATED APPLICATION

This application is based upon and claims the benefit of priority from the prior Japanese Patent Application No. 2010-199933, filed on Sep. 7, 2010, the entire contents of which are incorporated herein by reference.

### FIELD

Embodiments described herein relate generally to a digital/analog converter that converts an input digital signal to an analog signal and outputs the analog signal.

### BACKGROUND

Conventionally, there is a current-steering type digital/analog converter that outputs an analog signal by controlling the total amount of predetermined currents according to a digital signal.

### BRIEF DESCRIPTION OF THE DRAWINGS

FIG. 1 is a diagram showing an example of the configuration of a digital/analog converter 100 according to a first embodiment;

FIG. 2 is a diagram showing an example of the configuration of a control circuit 101 shown in FIG. 1;

FIG. 3 is a waveform diagram showing an example of the waveform of the analog signal Out output from the digital/analog converter 100 shown in FIG. 1;

FIG. 4 is a waveform diagram showing an example of the waveform of the gate control signals CS (the gate voltages of the third transistor 1d-1 and the fourth transistor 1e-1) of the digital/analog converter 100 shown in FIG. 1; and

FIG. 5 is a waveform diagram showing an example of the waveform of the output current I of the variable current circuit 103 of the control circuit 101 in the digital/analog converter 100 shown in FIG. 1.

### DETAILED DESCRIPTION

A digital/analog converter converts an input digital signal to an analog signal and outputs the analog signal according to an embodiment. The digital/analog converter has first and second transistors that are complementarily switched by a first digital signal included in the digital signal. The digital/analog converter has a first current source having a first end connected to a first potential, and having a second end connected to a first end of the first transistor and a first end of the second transistor, to output a constant current. The digital/analog converter has a third transistor having a first end connected to a second end of the first transistor. The digital/analog converter has a fourth transistor having a first end connected to a second end of the second transistor. The digital/analog converter has a first output terminal connected to a second end of the third transistor to output a first analog signal. The digital/analog converter has a control circuit that controls gate voltages of the third transistor and the fourth transistor according to the digital signal such that the third transistor and the fourth transistor operate in a saturation region.

Hereafter, embodiments of the present invention will be described with reference to the drawings.

### First Embodiment

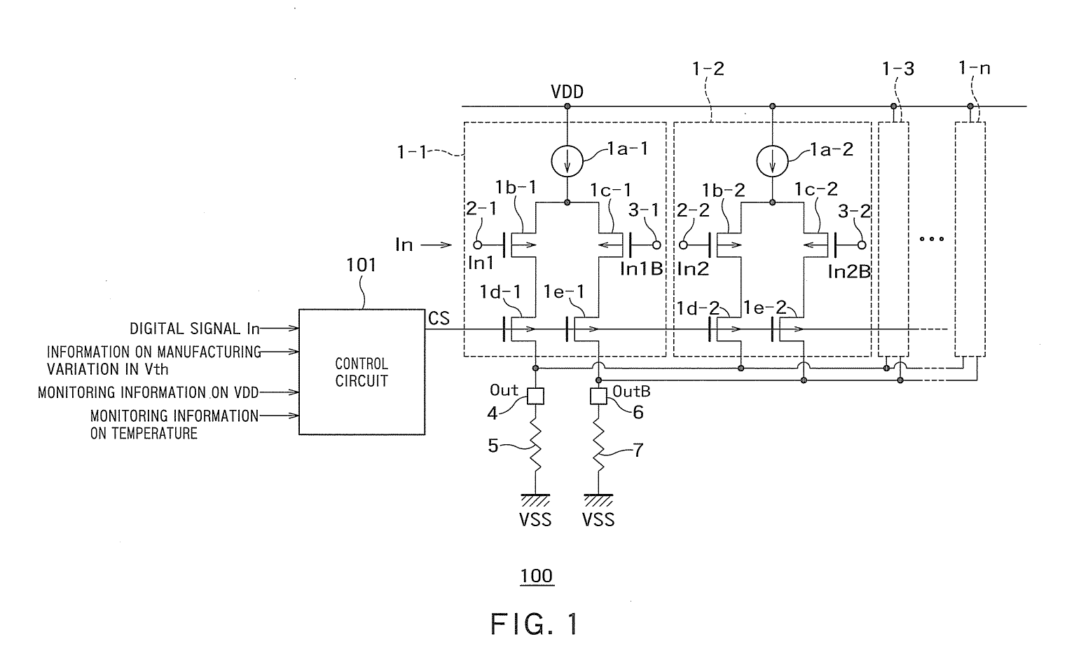

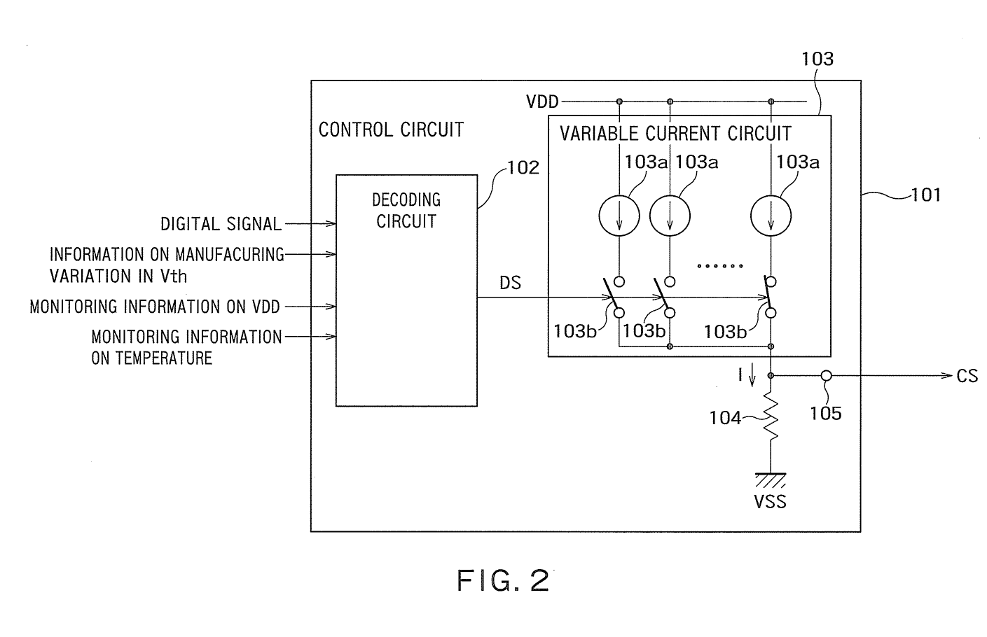

FIG. 1 is a diagram showing an example of the configuration of a digital/analog converter 100 according to a first embodiment, and FIG. 2 is a diagram showing an example of the configuration of a control circuit 101 shown in FIG. 1.

FIG. 1 shows an example in which a first potential is defined as a power supply potential VDD, a second potential is defined as a ground potential VSS, and each transistor is a pMOS transistor. When reversing the polarity of the circuit, the first potential is the ground potential VSS, the second potential is the power supply potential VDD, and each transistor is an nMOS transistor.

As shown in FIG. 1, the digital/analog converter 100, which converts an input digital signal to an analog signal and outputs an analog signal, includes a plurality (e.g., n (n≧2)) of current source cells 1-1, 1-2, . . . , and 1-n, a first output terminal 4, a second output terminal 6, a first resistive element 5, a second resistive element 7, and a control circuit 101.

The current source cell 1-1 includes a first current source 1a-1, a first transistor (a pMOS transistor) 1b-1, a second transistor (a pMOS transistor) 1c-1, a third transistor (a pMOS transistor) 1d-1, a fourth transistor (a pMOS transistor) 1e-1, a first input terminal 2-1, and a second input terminal 3-1.

First digital signals In1 and In1B included in a digital signal In input to the digital/analog converter 100 are differentially input to the first input terminal 2-i and the second input terminal 3-1.

The first current source 1a-1 has one end connected to the first potential VDD and is configured to output a constant current.

The first transistor 1b-1 has one end (a source) connected to the other end of the first current source 1a-1, and a gate connected to the first input terminal 2-1.

The second transistor 1c-1 has one end (a source) connected to the other end of the first current source 1a-1, and a gate connected to the second input terminal 3-1.

The third transistor 1d-1 has one end (a source) connected to the other end (a drain) of the first transistor 1b-1, and the other end (a drain) connected to the second potential VSS different from the first potential VDD through the first resistive element 5.

The fourth transistor 1e-1 has one end (a source) connected to the other end (a drain) of the second transistor 1c-1, and the other tend (a drain) connected to the second potential VSS through the second resistive element 7.

In addition, a gate of the third transistor 1d-1, for example, is connected to a gate of the fourth transistor 1e-1.

Furthermore, the third transistor 1d-1, for example, is set to have the same size as that of the fourth transistor 1e-1.

Furthermore, the current source cell 1-2 includes a second current source 1a-2, a fifth transistor (a pMOS transistor) 1b-2, a sixth transistor (a pMOS transistor) 1c-2, a seventh transistor (a pMOS transistor) 1d-2, an eighth transistor (a pMOS transistor) 1e-2, a third input terminal 2-2, and a fourth input terminal 3-2.

Second digital signals In2 and In2B included in the digital signal In are differentially input to the third input terminal 2-2 and the fourth input terminal 3-2.

The second current source 1a-2 has one end connected to the first potential VDD and is configured to output a constant current.

The fifth transistor 1b-2 has one end (a source) connected to the other end of the second current source 1a-2, and a gate connected to the third input terminal 2-2.

The sixth transistor 1c-2 has one end (a source) connected to the other end of the second current source 1a-2, and a gate connected to the fourth input terminal 3-2.

The seventh transistor 1d-2 has one end (a source) connected to the other end (a drain) of the fifth transistor 1b-2, and the other end (a drain) connected to the other end (a drain) of the third transistor 1d-1.

The eighth transistor 1e-2 has one end (a source) connected to the other end (a drain) of the sixth transistor 1c-2, and the other tend (a drain) connected to the other end of the fourth transistor 1e-1.

In addition, a gate of the seventh transistor 1d-2, for example, is connected to a gate of the eighth transistor 1e-2.

Furthermore, the seventh transistor 1d-2, for example, is set to have the same size as the eighth transistor 1e-2.

In the same manner, the other current source cells 1-3 to 1-n also have the same configuration as those of the current source cells 1-1 and 1-2, and the third to n^{th} digital signals included in the digital signal In are differentially input thereto. That is, the digital signal In includes the first to n^{th} digital signals corresponding to respective bits constituting the digital signal In. Hereinafter, the operation of the current source cell 1-1 will be described. However, it is assumed that the other current source cells perform the same operation.

The control circuit 101 is configured to output a gate control signal CS according to the digital signal In and control the gate voltages of the third transistor 1d-1 and the fourth transistor 1e-1 such that the third transistor 1d-1 and the fourth transistor 1e-1 of the current source cell 1-1 operate in a saturation region. In addition, the control circuit 101 is configured to control the current source cells 1-2 to 1-n in the same manner as above.

That is, when a current flowing through the first resistive element 5 and the second resistive element 7 increases according to the digital signal In, the control circuit 101 controls the third transistor 1d-i and the fourth transistor 1e-1 such that the gate voltages of the third transistor 1d-1 and the fourth transistor 1e-1 approach (increase to) the first potential VDD.

Meanwhile, when the current flowing through the first resistive element 5 and the second resistive element 7 decreases according to the digital signal In, the control circuit 101 controls the third transistor 1d-1 and the fourth transistor 1e-1 such that the gate voltages of the third transistor 1d-1 and the fourth transistor 1e-1 approach (decrease to) the second potential VSS.

In addition, the control circuit 101 is configured to monitor the first potential (the power supply potential) VDD or the temperature of a device including the digital/analog circuit of the embodiment, and to control the gate voltages of the third transistor 1d-1 and the fourth transistor 1e-1 such that the third transistor 1d-1 and the fourth transistor 1e-1 operate in the saturation region according to the first potential VDD or the temperature. That is, the control circuit 101 controls the gate voltages of the third transistor and the fourth transistor according to a change in a threshold voltage due to a change in the VDD or the temperature.

Here, in order to allow a transistor to operate in the saturation region, it is necessary to satisfy the relational expression of Vds (a voltage between a drain and a source)>Vgs (a voltage between a gate and a source)−Vth (a threshold voltage). Therefore, for example, when the threshold voltage Vth is increased by a reduction in the temperature or an increase in a power supply voltage, even if the gate control signal CS is set to be low, it is possible for the transistor to operate in the saturation region (the relational expression is satisfied). As a result, wasteful power consumption can be reduced. Meanwhile, for example, when the threshold voltage Vth is reduced by an increase in the temperature or a reduction in the power supply voltage, the transistor is allowed to operate in the saturation region by setting the value of the gate control signal CS to be high.

In addition, the control circuit 101 is configured to control the gate voltages of the third transistor 1d-1 and the fourth transistor 1e-1 such that the third transistor 1d-1 and the fourth transistor 1e-1 operate in the saturation region according to a manufacturing variation in the threshold voltages of the third transistor 1d-1 and the fourth transistor 1e-1.

The input signal of the control circuit 101 according to the embodiment includes a digital signal, information on a manufacturing variation in the Vth, monitoring information on the VDD, and monitoring information on the temperature. However, it is not necessary to input all these signals, and the embodiment can be performed if any one of the input signals is input.

As shown in FIG. 2, the control circuit 101, for example, includes a decoding circuit 102, a variable current circuit 103, a resistance circuit 104, and a control output terminal 105.

The decoding circuit 102 is configured to output a decoding signal DS obtained by decoding the digital signal In or a signal corresponding to the digital signal In.

The variable current circuit 103 is configured to change an output current I according to the decoding signal DS.

The resistance circuit 104 is connected between output of the variable current circuit 103 and the second potential VSS.

The control output terminal 105 is connected between the output of the variable current circuit 103 and the resistance circuit 104 to output the gate control signal CS for controlling the gate voltages of the third transistor 1d-1 and the fourth transistor 1e-1.

The variable current circuit 103, for example, includes a plurality of current sources 103a and a plurality of switching elements 103b.

The plurality of current sources 103a have one end connected to the first potential VDD to output a constant current.

Furthermore, the plurality of switching elements 103b have one end connected to the other end of the plurality of current sources 103a in a one-to-one fashion and the other end connected to the control output terminal 105, and are turned on or off according to the decoding signal DS.

The output current I of the variable current circuit 103 is the sum of currents output from the current sources 103a through switching elements 103b being turned on.

A change occurs in the output current I of the variable current circuit 103 by turning on/off of each switching element 103b according to the decoding signal DS. That is, the output current I increases by increasing the number of switching elements 103b being turned on. Thus, the potential of the control output terminal 105 rises. Meanwhile, the output current I decreases by decreasing the number of switching elements 103b being turned on. Thus, the potential of the control output terminal 105 drops.

In addition, FIG. 2 shows an example in which one variable current circuit 103, one resistance circuit 104, and one control output terminal 105 are provided with respect to the current source cells 1-1 to 1-n. However, n variable current circuits 103, n resistance circuits 104, and n control output terminals 105 may be provided with respect to the current source cells 1-1 to 1-n in a one-to-one fashion.

Furthermore, as shown in FIG. 1, the first output terminal 4 is connected to the other end (the drain) of the third transistor 1d-1 to output a first analog signal Out.

Furthermore, the first resistive element 5 is connected between the first output terminal 4 and the second potential VSS.

Furthermore, the second output terminal 6 is connected to the other end (the drain) of the fourth transistor 1e-1 to output a second analog signal OutB which is complementary to the first analog signal Out. That is, analog differential signals are output from the first output terminal 4 and the second output terminal 6.

Furthermore, the second resistive element 7 is connected between the second output terminal 6 and the second potential VSS.

In addition, the second output terminal 6 and the second resistive element 7, for example, may be omitted when no differential signal is necessary.

Next, the characteristics of the digital/analog converter 100 having the above configuration will be reviewed in the case where the digital/analog converter 100 operates with a sign wave as an example.

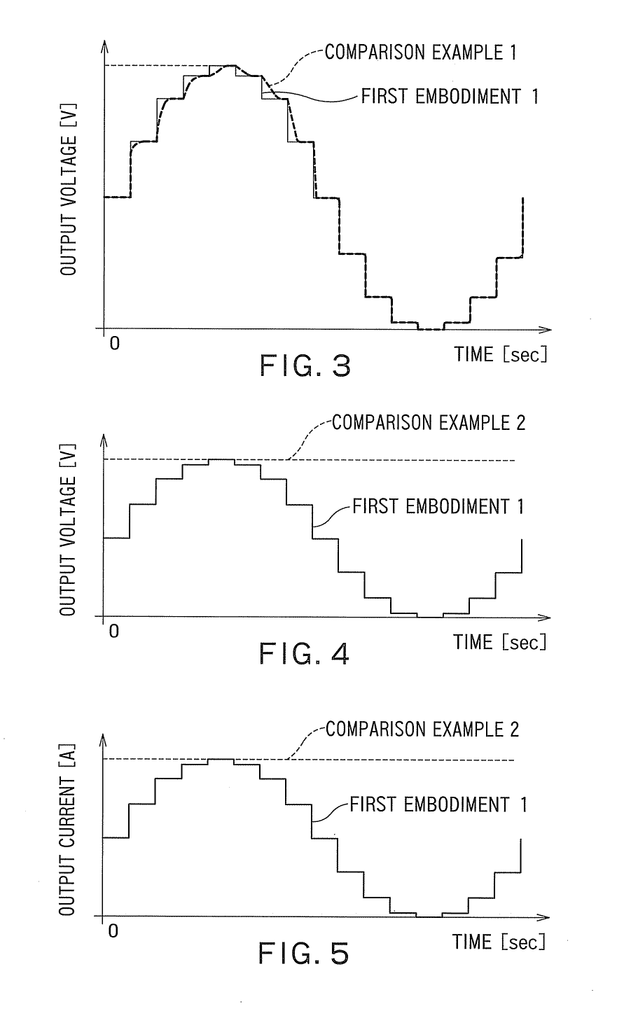

FIG. 3 is a waveform diagram showing an example of the waveform of the analog signal Out output from the digital/analog converter 100 shown in FIG. 1. FIG. 4 is a waveform diagram showing an example of the waveform of the gate control signals CS (the gate voltages of the third transistor 1d-1 and the fourth transistor 1e-1) of the digital/analog converter 100 shown in FIG. 1. FIG. 5 is a waveform diagram showing an example of the waveform of the output current I of the variable current circuit 103 of the control circuit 101 in the digital/analog converter 100 shown in FIG. 1. In addition, FIGS. 3 to 5 show comparison examples 1 and 2 in order to represent the effectiveness of this embodiment. The comparison example 1 shows a digital/analog circuit in which the third transistor 1d-1 and the fourth transistor 1e-1 of this embodiment do not exist, and the comparison example 2 shows an example in which the gate control signals CS have a fixed value, that is, the third transistor 1d-1 and the fourth transistor 1e-1 are always in a conduction state. The solid line indicates the first embodiment and the dotted lines indicate the comparison examples.

As shown in FIG. 3, when an output voltage (the analog signal Out) is low, since the third transistor 1d-1 and the fourth transistor 1e-1 can operate in a saturation region in both the first embodiment and the comparison example 1, no distortion occurs in the output voltage (the analog signal Out).

Meanwhile, when the output voltage (the analog signal Out) is increased according to the digital signal In, since the third transistor 1d-1 and the fourth transistor 1e-1 operate in a linear region in the comparison example 1, distortion occurs in the output voltage (the analog signal Out).

However, in the first embodiment, although when the output voltage (the analog signal Out) is increased according to the digital signal In, the gate voltages of the third transistor 1d-1 and the fourth transistor 1e-1 are controlled according to the digital signal In such that the third transistor 1d-1 and the fourth transistor 1e-1 operate in a saturation region. Thus, since the third transistor 1d-1 and the fourth transistor 1e-1 can operate in the saturation region, no distortion occurs in the output voltage (the analog signal Out).

As shown in FIG. 4, the gate voltages of the third transistor 1d-1 and the fourth transistor 1e-1 are fixed at a high potential (the comparison 2), so that the third transistor 1d-1 and the fourth transistor 1e-1 operate in the saturation region, resulting in the prevention of the distortion occurring in the comparison 1 of FIG. 3.

However, as shown in FIG. 5, in the case of the comparison 2, the output current of the control circuit 101, that is, current consumption of the digital/analog converter 100 is large.

Meanwhile, according to the first embodiment, when the output voltage (the analog signal Out) is reduced according to the digital signal In, the gate voltages of the third transistor 1d-1 and the fourth transistor 1e-1 are reduced according to the digital signal In in the range in which the third transistor 1d-1 and the fourth transistor 1e-1 operate in the saturation region. Thus, it is possible to reduce the output current of the control circuit 101, that is, the current consumption of the digital/analog converter 100.

Because, the third and fourth transistors operate in a saturation region around a boundary between the saturation region and a linear region, the current consumption is more reduced.

That is, according to the digital/analog converter in accordance with the first embodiment, it is possible to reduce the current consumption and the distortion of the output signal.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A digital/analog converter that converts an input digital signal to an analog signal and outputs the analog signal, comprising:
a first transistor and a second transistor that are complementarily switched by a first digital signal included in the digital signal;
a first current source having a first end connected to a first potential, and having a second end connected to a first end of the first transistor and a first end of the second transistor, to output a constant current;
a third transistor having a first end connected to a second end of the first transistor;
a fourth transistor having a first end connected to a second end of the second transistor;
a first output terminal connected to a second end of the third transistor to output a first analog signal; and
a control circuit that controls gate voltages of the third transistor and the fourth transistor according to the digital signal such that the third transistor and the fourth transistor operate in a saturation region.

2. The digital/analog converter of claim 1, wherein the control circuit controls the gate voltage of the third transistor and the gate voltage of the fourth transistor according to the digital signal such that the third transistor and the fourth transistor operate in a saturation region around a boundary between the saturation region and a linear region.

3. The digital/analog converter of claim 1, further comprising a first resistive element connected between the first output terminal and a second potential, the second potential being different from the first potential.

4. The digital/analog converter of claim 3, wherein the control circuit controls the gate voltage of the third transistor and the gate voltage of the fourth transistor to approach the first potential when a current flowing through the first resistive element increases according to the digital signal, and controls the gate voltage of the third transistor and the gate voltage of the fourth transistor to approach the second potential when the current flowing through the first resistive element decreases according to the digital signal.

5. The digital/analog converter of claim 3, wherein the control circuit comprising:
a decoding circuit that is configured to output a decoding signal obtained by decoding the digital signal;
a variable current circuit that is configured to change an output current according to the decoding signal;
a resistance circuit that is connected between an output of the variable current circuit and the second potential; and
a control output terminal that is connected between the output of the variable current circuit and the resistance circuit to output a gate control signal for controlling the gate voltages of the third transistor and the fourth transistor.

6. The digital/analog converter of claim 5, wherein the variable current circuit comprising:
a plurality of current sources that have one end connected to the first potential; and
a plurality of switching elements that have one end connected to the other end of the plurality of current sources in a one-to-one fashion and the other end connected to the control output terminal, and are turned on or off according to the decoding signal.

7. The digital/analog converter of claim 1, wherein the control circuit monitors the first potential or a temperature of the third and fourth transistors, and controls the gate voltages of the third transistor and the fourth transistor such that the third transistor and the fourth transistor operate in the saturation region according to the first potential or the temperature.

8. The digital/analog converter of claim 1, wherein the control circuit controls the gate voltages of the third transistor and the fourth transistor such that the third transistor and the fourth transistor operate in the saturation region according to a manufacturing variation in the threshold voltages of the third transistor and the fourth transistor.

9. The digital/analog converter of claim 3, further comprising:
a second output terminal that is connected to a second end of the fourth transistor to output a second analog signal, the second analog signal being complementary to the first analog signal; and
a second resistive element connected between the second output terminal and the second potential.

10. The digital/analog converter of claim 1, wherein
the first potential is a power supply potential,
the second potential is a ground potential, and
the first to fourth transistors are pMOS transistors.

11. The digital/analog converter of claim 1, further comprising:
a second current source having a first end connected to the first potential to output a constant current;
a fifth transistor having a first end connected to a second end of the second current source, and having a gate connected to the third input terminal;
a sixth transistor having a first end connected the second end of the second current source, and having a gate connected to the fourth input terminal, the fifth and sixth transistors being complementarily switched by a second digital signal included in the digital signal;
a seventh transistor having a first end connected to a second end of the fifth transistor, and having a second end connected to the second end of the third transistor; and
an eighth transistor having a first end connected to a second end of the sixth transistor, and having a second end connected to the second end of the fourth transistor, wherein
the control circuit controls gate voltages of the seventh and eighth transistors according to the digital signal such that the seventh and eighth transistors operate in a saturation region.

12. A digital/analog converter that converts an input digital signal to an analog signal and outputs the analog signal, comprising:
a first input terminal and a second input terminal, a first digital signal included in a digital signal being differentially input to the first input terminal and the second input terminal;
a first current source having a first end connected to a first potential to output a constant current;
a first transistor having a first end connected to a second end of the first current source, and having a gate connected to the first input terminal;
a second transistor having a first end connected the second end of the first current source, and having a gate connected to the second input terminal;
a third transistor having a first end connected to a second end of the first transistor;
a fourth transistor having a first end connected to a second end of the second transistor;
a first output terminal connected to a second end of the third transistor to output a first analog signal; and
a control circuit that monitors the first potential or a temperature of the third and fourth transistors, and controls gate voltages of the third transistor and the fourth transistor such that the third transistor and the fourth transistor operate in a saturation region according to the first potential or the temperature.

13. The digital/analog converter of claim 12, wherein the control circuit controls the gate voltage of the third transistor and the gate voltage of the fourth transistor according to the digital signal such that the third transistor and the fourth transistor operate in a saturation region around a boundary between the saturation region and a linear region.

14. The digital/analog converter of claim 12, further comprising a first resistive element connected between the first output terminal and a second potential, the second potential being different from the first potential.

15. The digital/analog converter of claim 14, wherein the control circuit controls the gate voltage of the third transistor and the gate voltage of the fourth transistor to approach the first potential when a current flowing through the first resistive element increases according to the digital signal, and controls the gate voltage of the third transistor and the gate voltage of the fourth transistor to approach the second potential when the current flowing through the first resistive element decreases according to the digital signal.

16. The digital/analog converter of claim 12, wherein the control circuit comprising:
a decoding circuit that is configured to output a decoding signal obtained by decoding the digital signal;
a variable current circuit that is configured to change an output current according to the decoding signal;
a resistance circuit that is connected between an output of the variable current circuit and the second potential; and
a control output terminal that is connected between the output of the variable current circuit and the resistance circuit to output the gate control signal for controlling the gate voltages of the third transistor and the fourth transistor.

17. The digital/analog converter of claim 16, wherein the variable current circuit comprising:
a plurality of current sources that have one end connected to the first potential; and
a plurality of switching elements that have one end connected to the other end of the plurality of current sources in a one-to-one fashion and the other end connected to the control output terminal, and are turned on or off according to the decoding signal.

18. The digital/analog converter of claim 12, wherein the control circuit controls the gate voltages of the third transistor and the fourth transistor such that the third transistor and the fourth transistor operate in the saturation region according to a manufacturing variation in the threshold voltages of the third transistor and the fourth transistor.

19. The digital/analog converter of claim 12, further comprising:
a second output terminal that is connected to a second end of the fourth transistor to output a second analog signal, the second analog signal being complementary to the first analog signal; and
a second resistive element connected between the second output terminal and the second potential.

20. The digital/analog converter of claim 12, wherein
the first potential is a power supply potential,
the second potential is a ground potential, and
the first to fourth transistors are pMOS transistors.
